(19) United States
(12) Patent Application Publication
(10) Pub. No.: US 2026/0198212 A1
(43) Pub. Date: Jul. 9, 2026

(54) DISPLAY DEVICE AND ELECTRONIC DEVICE HAVING THE SAME

(71) Applicant: Samsung Display Co., Ltd., Yongin-Si (KR)

(72) Inventors: Dong Chul SHIN, Yongin-si (KR); Hyo Joon KIM, Yongin-si (KR); Ju Youn SON, Yongin-si (KR)

(21) Appl. No.: 19/408,807

(22) Filed: Dec. 4, 2025

(30) Foreign Application Priority Data
Jan. 8, 2025 (KR) 10-2025-0002995

(51) Int. Cl. H10K 59/80; H10K 50/19; H10K 59/38; H10K 102/00

(52) U.S. Cl. CPC H10K 59/879; H10K 59/38; H10K 59/876; H10K 59/8791; H10K 50/19; H10K 2102/331

(57) ABSTRACT

A display device may include: a substrate; a light emitting element layer disposed on the substrate and including sub-pixels emitting light; a micro-lens array disposed on the light emitting element layer and including at least one micro-lens; a first optical system disposed directly on the micro-lens array; and a second optical system including a module lens and disposed above the first optical system. The first optical system may include a low refractive layer disposed on the micro-lens array; a meta-lens disposed on the low refractive layer; a first polarizing layer disposed on the meta-lens; and a first phase retardation layer disposed on the first polarizing layer. The first phase retardation layer may have a thickness corresponding to a chief ray angle of the module lens.

### CROSS-REFERENCE TO RELATED APPLICATION

The application claims priority under 35 U.S.C. § 119(a) to Korean patent application No. 10-2025-0002995 filed on Jan. 8, 2025, in the Korean Intellectual Property Office, the entire disclosure of which is incorporated herein by reference.

### BACKGROUND

### 1. Technical Field

The disclosure generally relates to a display device and an electronic device including the display device.

### 2. Related Art

In recent years, as interest in information displays increases, research and development have been consistently conducted for display devices.

### SUMMARY

Embodiments provide a display device with improved reliability and an electronic device including the same.

According to embodiments of the disclosure, a display device includes a substrate; a light emitting element layer disposed on the substrate and including sub-pixels emitting light; a micro-lens array disposed on the light emitting element layer and including at least one micro-lens; a first optical system disposed directly on the micro-lens array; and a second optical system including a module lens and disposed above the first optical system. The first optical system may include a low refractive layer disposed on the micro-lens array; a meta-lens disposed on the low refractive layer; a first polarizing layer disposed on the meta-lens; and a first phase retardation layer disposed on the first polarizing layer. The first phase retardation layer may have a thickness corresponding to a chief ray angle of the module lens.

The module lens may include a pancake lens.

The first phase retardation layer may be a quarter wave plate.

The meta-lens may control a path of light passing through the micro-lens array to correspond to the chief ray angle of the pancake lens.

The meta-lens includes a nanostructure disposed on a base layer.

The light emitting element layer may include a light emitting element having a strong resonance structure.

The light emitting element layer may include a planarization layer disposed on the substrate and the light emitting element disposed on the planarization layer. The light emitting element may include an anode electrode disposed on the planarization layer of each of the sub-pixels; a pixel defining layer disposed on the planarization layer, the pixel defining layer defining a light emitting area of each of the sub-pixels; a light emitting structure disposed on the pixel defining layer; and a cathode electrode disposed on the light emitting structure.

The light emitting structure may include a first emission component disposed on the anode electrode, the first emission component emitting light; an intermediate layer disposed on the first emission component; and a second emission component disposed on the intermediate layer, the second emission component emitting light.

The first polarizing layer may be a wire grid polarizing plate.

The second optical system may include a half mirror disposed above the first optical system; a second phase retardation layer disposed on the half mirror; a second polarizing layer disposed on the second phase retardation layer; and at least one lens disposed on the half mirror.

The second phase retardation layer may include a λ/4 phase retardation plate.

The second polarizing layer may be a reflective polarizing plate.

The lens may include a first lens disposed between the half mirror and the second phase retardation layer; and a second lens disposed on the second polarizing layer.

The display device may further include a color filter layer disposed between the light emitting element layer and the micro-lens array. The color filter layer may include at least one color filter.

According to embodiments of the disclosure, an electronic device includes a display device configured to display an image; and a processor configured to provide input image data to the display device. The display device may include a substrate; a light emitting element layer disposed on the substrate and including sub-pixels emitting light; a micro-lens array disposed on the light emitting element layer and including at least one micro-lens; a first optical system disposed directly on the micro-lens array; and a second optical system disposed above the first optical system and including a module lens. The first optical system may include a low refractive layer disposed on the micro-lens array; a meta-lens disposed on the low refractive layer; a first polarizing layer disposed on the meta-lens; and a first phase retardation layer disposed on the first polarizing layer. The first phase retardation layer may have a thickness corresponding to a chief ray angle of the module lens.

The module lens may include a pancake lens.

The first phase retardation layer may be a quarter wave plate.

The meta-lens may control a path of light passing through the micro-lens array to correspond to the chief ray angle of the pancake lens.

The meta-lens includes a nanostructure disposed on a base layer.

The light emitting element layer may include a light emitting element having a strong resonance structure.

According to embodiments of the disclosure, a meta-lens for controlling a path of light emitted from a light emitting element layer to correspond to a chief ray angle of a pancake lens and a quarter wave plate having different thicknesses according to the chief ray angle are disposed between the pancake lens and the light emitting element layer having a light emitting element having the strong resonance structure. In this case, the reliability of the display device may be improved by improving performance degradation according to the incident angle of light incident on the pancake lens.

The effects of the present disclosure are not limited by the foregoing, and other various effects are anticipated herein.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawings, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic block diagram of a display device according to some embodiments of the disclosure.

FIG. 2 is a schematic block diagram illustrating some embodiments of one of the sub-pixels of FIG. 1.

FIG. 3 is a schematic circuit diagram illustrating some embodiments of the sub-pixel shown in FIG. 2.

FIG. 4 is a schematic plan view illustrating an embodiment of the display device of FIG. 1.

FIG. 5 is a schematic exploded perspective view illustrating a portion of a display device in accordance with embodiments of the disclosure.

FIG. 6 is a schematic plan view illustrating an embodiment of one of the pixels of FIG. 5.

FIG. 7 is a schematic cross-sectional view taken along the line I~I′ of FIG. 6.

FIG. 8 is a schematic cross-sectional view illustrating a portion of a light emitting element layer included in the display device of FIG. 7.

FIG. 9 is a schematic cross-sectional view illustrating the meta-lens of FIG. 7.

FIG. 10 is a schematic perspective view illustrating a display device according to an embodiment.

FIG. 11 is a schematic exploded perspective view illustrating the display device of FIG. 10.

FIG. 12 is a schematic conceptual diagram for describing a chief ray angle incident from a display panel to a module lens.

FIG. 13 is a schematic diagram illustrating a display panel and a second optical system according to an embodiment.

FIG. 14 is a schematic enlarged view of portion EA shown in FIG. 13.

FIG. 15 is a schematic block diagram illustrating an electronic device in accordance with embodiments of the disclosure.

FIG. 16 shows schematic views of various embodiments of an electronic device.

### DETAILED DESCRIPTION

Hereinafter, embodiments according to the present disclosure will be described in detail with reference to the accompanying drawings. It should be noted that the following explanation describes only parts necessary to understand the operation of the present disclosure, and other parts of the description will be omitted not to obscure the gist of the present disclosure. In addition, the present disclosure is not limited to the embodiments described herein, but may be embodied in other forms. However, the embodiment described herein is provided to explain in such detail as to facilitate implementation of the technical idea of the present disclosure to a person skilled in the art to which the present disclosure pertains.

Throughout the specification, if a part is “connected” to another part, this includes not only a case where they are “directly connected”, but also a case where they are “indirectly connected” with another element interposed therebetween. Terminology used herein is intended to describe specific embodiments and is not intended to limit the present disclosure. Throughout the specification, if a part “comprises” or “includes” a component, it means that it may further include other component rather than excluding other components unless the context indicates otherwise. “At least any one of X, Y, and Z” and “at least any one selected from a group of X, Y, and Z” may be interpreted as one X, one Y, one Z, or a combination of two or more of X, Y, and Z (e.g., XYZ, XYY, YZ, ZZ). Herein, “and/or” includes all combinations of one or more of corresponding configurations.

Herein, terms such as first and second may be used to describe various components, but these components are not limited to these terms. These terms are used to distinguish one component from another component. Accordingly, a first component may be referred to as a second component without departing from the present disclosure.

Spatially relative terms such as “below” and “above” may be used for illustrative purposes, thereby describing the relationship of one element or feature to another element(s) or feature(s) as shown in the drawings. The spatially relative term is intended to include different orientations in use, operation, and/or manufacture, in addition to the orientation depicted in the drawing. For example, if a device shown in the drawing is turned over, elements depicted as being positioned “below” other elements or features are positioned “above” the other elements or features. Hence, the term “below” may include both upward and downward directions in an embodiment. Besides, the device may be oriented in other directions (e.g., rotated 90 degrees or in a different direction), and thus the spatially relative terms used herein are interpreted accordingly.

Various embodiments are described with reference to drawings illustrating ideal embodiments. Accordingly, it is to be expected, for example, that shapes may change depending on tolerances and/or manufacturing techniques. Thus, the embodiments disclosed herein may not be construed as being limited to the specific shapes depicted, but should be construed as including variations of the shapes resulting from, for example, manufacturing. As such, the shapes shown in the drawings may not show actual shapes of areas of the device, and the present embodiments are not limited thereto.

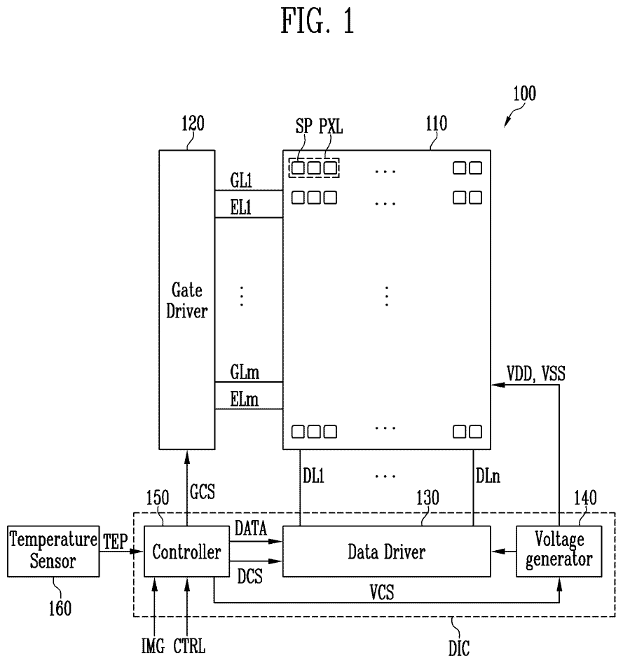

FIG. 1 is a schematic block diagram of a display device 100 according to some embodiments of the disclosure.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, each of the sub-pixels SP may generate light of a particular color, such as red, green, blue, cyan, magenta, and yellow. Two or more of the sub-pixels SP may form a single pixel PXL. For example, the pixel PXL may include three sub-pixels, as shown in FIG. 1, but is not limited thereto.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating the start of each frame, a horizontal synchronization signal for outputting gate signals in synchronization with the timing at which data signals are applied, and the like.

In embodiments, first to m-th emission control lines EL1 to ELm connected to the sub-pixels SP in the row direction may be further provided. In this case, the gate driver 120 may include an emission control driver configured to control the first to m-th emission control lines EL1 to ELm. The emission control driver may operate under the control of the controller 150.

The gate driver 120 may be disposed on one side of the display panel 110. However, embodiments are not limited thereto. For example, the gate driver 120 may include two or more physically and/or logically separated drivers, and the drivers may be disposed on one side of the display panel 110 and the other side of the display panel 110 opposite to the one side. As described above, the gate driver 120 may be disposed around the display panel 110 in various forms according to the embodiments.

The data driver 130 may be connected to the sub-pixels SP arranged in a column direction through the first to n-th data lines DL1 to DLn. The data driver 130 may receive image data (DATA) and a data control signal DCS from the controller 150. The data driver 130 may operate in response to the data control signal DCS. In embodiments, the data control signal DCS may include a source start pulse, a source shift clock, a source output enable signal, and the like.

The data driver 130 may use voltages from the voltage generator 140 to apply data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLm. Accordingly, the corresponding sub-pixels SP may generate light corresponding to the data signals. Accordingly, an image may be displayed on the display panel 110.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to constituent elements of the display device 100. For example, the voltage generator 140 may be configured to generate a plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level and the second power voltage VSS may have a voltage level lower than the first power voltage VDD. In other embodiments, the first power voltage VDD and/or the second power voltage VSS may be provided by an external device of the display device 100.

In addition, the voltage generator 140 may generate various voltages. For example, the voltage generator 140 may generate an initialization voltage applied to the sub-pixels SP. For example, upon the sensing operation to sense the electrical properties of transistors and/or light emitting elements of the sub-pixels SP, a predetermined reference voltage may be applied to the first to n-th data lines DL1 to DLn, and the voltage generator 140 may generate the reference voltage.

The controller 150 may control various operations of the display device 100. The controller 150 may receive input image data IMG and a control signal CTRL for controlling the display of the input image data, from the outside, for example, a central processing unit, an application processor, or the like. The controller 150 may provide the gate control signal GCS, the data control signal DCS, and the voltage control signal VCS in response to the control signal CTRL.

The controller 150 may convert the input image data IMG to be suitable for the display device 100 or the display panel 110 to output the image data DATA. In embodiments, the controller 150 may output the image data DATA by aligning the input image data IMG to be suitable for the sub-pixels SP of a row unit.

Two or more components of the data driver 130, the voltage generator 140, and the controller 150 may be integrated in one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate components within one driver integrated circuit DIC. In other embodiments, at least one of the data driver 130, the voltage generator 140, and the controller 150 may be provided as a component separated from the driver integrated circuit DIC.

The display device 100 may include at least one temperature sensor 160. The temperature sensor 160 may be configured to sense a surrounding temperature and generate temperature data TEP representing the sensed temperature. In embodiments, the temperature sensor 160 may be disposed adjacent to the display panel 110 and/or the driver integrated circuit DIC.

The controller 150 may control various operations of the display device 100 in response to the temperature data TEP. In embodiments, the controller 150 may adjust the luminance of an image outputted from the display panel 110 in response to the temperature data TEP. For example, the controller 150 may control the data signals and the first and second power voltages VDD and VSS by controlling components such as the data driver 130 and/or the voltage generator 140.

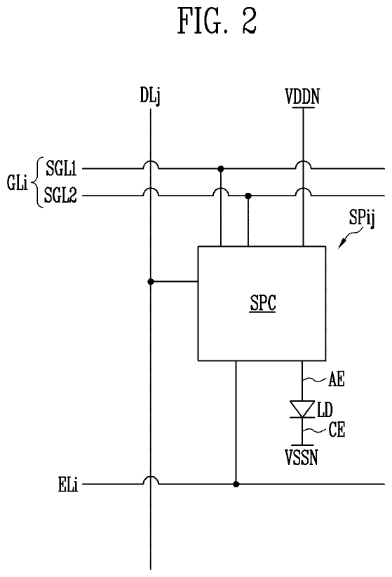

FIG. 2 is a schematic block diagram illustrating some embodiments of one of the sub-pixels of FIG. 1. In FIG. 2, among the sub-pixels SP of FIG. 1, a sub-pixel SPij disposed in an i-th row (i is an integer greater than or equal to 1 and less than or equal to m) and a j-th column (j is an integer greater than or equal to 1 and less than or equal to n) is illustrated as an example.

Referring to FIG. 2, the sub-pixel SPij may include a sub-pixel circuit SPC and a light emitting element LD.

The light emitting element LD may be connected between a first power voltage node VDDN and a second power voltage node VSSN. In this case, the first power voltage node VDDN may be a node that transmits the first power voltage VDD of FIG. 1, and the second power voltage node VSSN may be a node that transmits the second power voltage VSS of FIG. 1.

An anode electrode AE of the light emitting element LD may be connected to the first power voltage node VDDN through the sub-pixel circuit SPC, and a cathode electrode CE of the light emitting element LD may be connected to second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC may be configured to control the light emitting element LD according to signals received through these signal lines.

The sub-pixel circuit SPC may operate in response to a gate signal received through the i-th gate line GLi. The i-th gate line GLi may include one or more sub-gate lines. In embodiments, as shown in FIG. 2, when the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In embodiments, the i-th emission control line ELi may include one or more sub-emission control lines. In cast that the i-th emission control line ELi includes two or more sub-emission control lines, the sub-pixel circuit SPC may operate in response to emission control signals received through the corresponding sub-emission control lines.

The sub-pixel circuit SPC may receive a data signal through the j-th data line DLj. The sub-pixel circuit SPC may store a voltage corresponding to the data signal in response to at least one of the gate signals received through the first sub-gate line SGL1 and the second sub-gate line SGL2. In response to the emission control signal received through the i-th emission control line ELi, the sub-pixel circuit SPC may adjust the current flowing from the first power voltage node VDDN to the second power voltage node VSSN through the light emitting element LD according to the stored voltage. Accordingly, the light emitting element LD may generate light of luminance corresponding to the data signal.

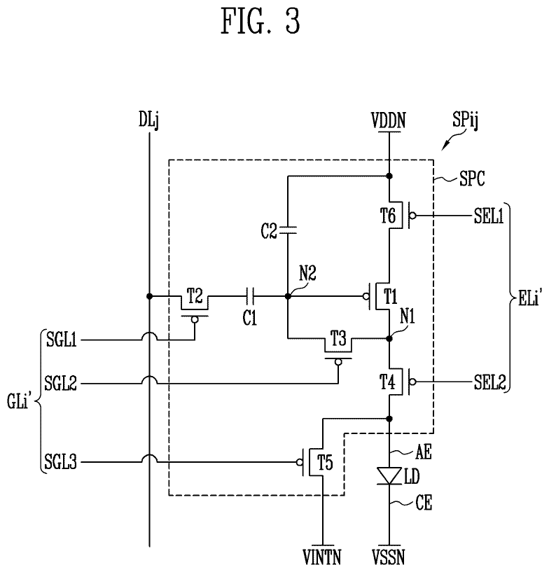

FIG. 3 is a schematic circuit diagram illustrating some embodiments of the sub-pixel SPij shown in FIG. 2.

Referring to FIG. 3, the sub-pixel SPij may include a sub-pixel circuit SPC and a light emitting element LD.

The sub-pixel circuit SPC may be connected to an i-th gate line GLi′, an i-th emission control line EL1′, and the j-th data line DLj. Compared to the i-th gate line GLi of FIG. 2, the i-th gate line GLi′ may further include a third sub-gate line SGL3. Compared to the i-th emission control line ELi of FIG. 2, the i-th emission control line ELi′ may include a first sub-emission control line SEL1 and a second sub-emission control line SEL2.

The sub-pixel circuit SPC may include first to sixth transistors T1 to T6, and first and second capacitors C1 and C2.

The first transistor T1 may be connected between the first power voltage node VDDN and a first node N1. A gate of the first transistor T1 may be connected to a second node N2, and thus the first transistor T1 may be turned on according to a voltage level of the second node N2. The first transistor T1 may be referred to as a driving transistor.

The second transistor T2 may be connected between the j-th data lines DLj and the second node N2. A gate of the second transistor T2 may be connected to the first sub-gate line SGL1, and thus the second transistor T2 may be turned on in response to a gate signal of the first sub-gate line SGL1. The second transistor T2 may be referred to as a switching transistor.

The third transistor T3 may be connected between the first node N1 and the second node N2. A gate of the third transistor T3 may be connected to the second sub-gate line SGL2, and thus the third transistor T3 may be turned on in response to a gate signal of the second sub-gate line SGL2.

The fourth transistor T4 may be connected between the first node N1 and the anode electrode AE of the light emitting element LD. A gate of the fourth transistor T4 may be connected to the second sub-emission control line SEL2, and thus the fourth transistor T4 may be turned on in response to an emission control signal of the second sub-emission control line SEL2.

The fifth transistor T5 may be connected between the anode electrode AE of the light emitting element LD and an initialization voltage node VINTN. The initialization voltage node VINTN may be configured to transfer an initialization voltage. In embodiments, the initialization voltage may be provided by the voltage generator 140 of FIG. 1. In another embodiments, the initialization voltage may be provided by an external device of the display device 100. A gate of the fifth transistor T5 may be connected to the third sub-gate line SGL3, and thus the fifth transistor T5 may be turned on in response to a gate signal of the third sub-gate line SGL3.

The sixth transistor T6 may be connected between the first power voltage node VDDN and the first transistor T1. A gate of the sixth transistor T6 may be connected to the first sub-emission control line SEL1, and thus the sixth transistor T6 may be turned on in response to an emission control signal of the first sub-emission control line SEL1.

The first capacitor C1 may be connected between the second transistor T2 and the second node N2. The second capacitor C2 may be connected between the first power voltage node VDDN and the second node N2.

As described above, the sub-pixel circuit SPC may include the first to sixth transistors T1 to T6, and the first and second capacitors C1 and C2. However, embodiments are not limited thereto. The sub-pixel circuit SPC may be implemented as any of various types of circuits including a plurality of transistors and one or more capacitors. For example, the sub-pixel circuit SPC may include two transistors and one capacitor. According to embodiments of the sub-pixel circuit SPC, the number of sub-gate lines included in the i-th gate line GLi′ and the number of sub-emission control lines included in the i-th emission control line ELi′ may vary.

The first to sixth transistors T1 to T6 may be P-type transistors. Each of the first to sixth transistors T1 to T6 may be a metal oxide silicon field effect transistor (MOSTEF). However, embodiments are not limited thereto. For example, at least one of the first to sixth transistors T1 to T6 may be replaced with an N-type transistor.

In embodiment, the first to sixth transistors T1 to T6 may include an amorphous silicon semiconductor, a monocrystalline silicon semiconductor, a polycrystalline silicon semiconductor, an oxide semiconductor, and the like.

The light emitting element LD may include the anode electrode AE, the cathode electrode CE, and a light emitting layer. The light emitting layer may be disposed between the anode electrode AE and the cathode electrode CE. After the data signal transferred through the j-th data line DLj is applied to the second node N2, the fourth and sixth transistors T4 and T6 may be turned on in response to the emission control signals of the first and second sub-emission control lines SEL1 and SEL2 having a low level. In addition, the first transistor T1 may be turned on according to the voltage of the second node N2, and thus a current may flow from the first power voltage node VDDN to the second power voltage node VSSN. The light emitting element LD may emit light according to an amount of the current flowing from the first power voltage node VDDN to the second power voltage node VSSN.

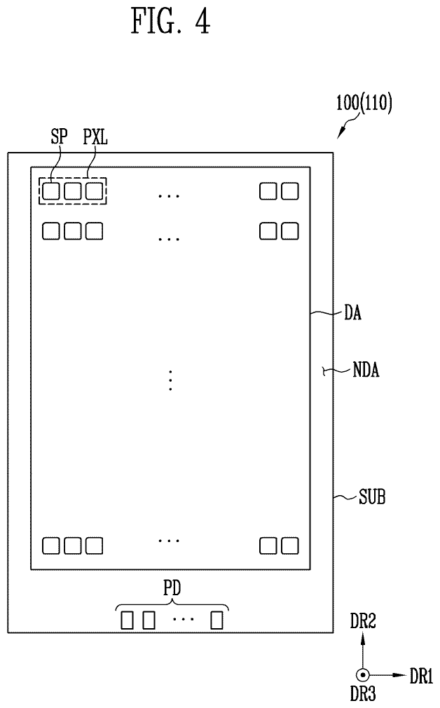

FIG. 4 is a schematic plan view illustrating an embodiment of the display device 100 of FIG. 1. For convenience, FIG. 4 schematically illustrates the structure of a display area DA of the display device 100 where an image is displayed, for example, the structure of the display panel 110 provided in the display device 100.

Referring to FIG. 4, the display panel 110 may include a display area DA and a non-display device NDA. The display panel 110 may display an image through the display area DA. The non-display area NDA may be disposed around the display area DA.

The display panel 110 may include a substrate SUB, the sub-pixels SP, and pads PD.

When the display panel 110 is used as a display screen of a head mounted display (HMD), a virtual reality (VR) device, a mixed reality (MR) device, an augmented reality (AR) device, or the like, the display panel 110 may be positioned very close to user's eyes. In this case, sub-pixels SP having high resolution are required. In order to increase of the resolution of the sub-pixels SP, a silicon substrate SUB may be required. The sub-pixels SP and/or the display panel 110 may be formed on the substrate SUB, which is the silicon substrate. The display device 100 including the display panel 110 formed on the substrate SUB, which is the silicon substrate, may be referred to as an OLED on silicon (OLEDoS) display device.

The sub-pixels SP may be disposed in the display area DA on the substrate SUB. The sub-pixels SP may be arranged in a matrix shape along a first direction DR1 and a second direction DR2 intersecting the first direction DR1. However, embodiments are not limited thereto. For example, the sub-pixels SP may be arranged in a zigzag pattern in the first direction DR1 and the second direction DR2. For example, the sub-pixels SP may be disposed in a PENTILE™ pattern. The first direction DR1 may be a row direction, and the second direction DR2 may be a column direction.

Two or more sub-pixels SP among the plurality of sub-pixels SP may configure one pixel PXL.

Components for controlling the sub-pixels SP may be disposed in the non-display area NDA on the substrate SUB. For example, wirings which are connected to the sub-pixels SP, such as the first to m-th gate lines GL1 to GLm and the first to n-th data lines DL1 to DLm of FIG. 1, may be disposed in the non-display area NDA.

At least one of the gate driver 120, the data driver 130, the voltage generator 140, the controller 150 and the temperature sensor 160 of FIG. 1 may be integrated in the non-display area NDA of the display panel 110. In embodiments, the gate driver 120 of FIG. 1 may be mounted in the display panel 110, and may be disposed in the non-display area NDA. In other embodiments, the gate driver 120 may be implemented as an integrated circuit which is separate from the display panel 110. In embodiments, the temperature sensor 160 may be disposed in the non-display area NDA to sense a temperature of the display panel 110.

The pads PD may be disposed in the non-display area NDA on the substrate SUB. The pads PD may be electrically connected to the sub-pixels SP via wirings. For example, the pads PD may be connected to the sub-pixels SP through the first to n-th data lines DL1 to DLn.

The pads PD may interface the display panel 110 to other components of the display device 100. In embodiments, voltages and signals necessary for an operation of components included in the display panel 110 may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS of FIG. 1 may be received from the driver integrated circuit DIC through the pads PD. For example, when the gate driver 120 is mounted in the display panel 110, the gate control signal GCS of FIG. 1 may be transmitted from the driver integrated circuit DIC to the gate driver 120 through the pads PD.

In embodiments, a circuit board may be electrically connected to the pads PD using a conductive adhesive member such as an anisotropic conductive film. The circuit board may be a flexible printed circuit board (FPCB) or a flexible film having a flexible material. The driver integrated circuit DIC may be mounted on the circuit board to be electrically connected to the pads PD.

In embodiments, the display area DA may have various shapes. The display area DA may have a closed loop shape including straight and/or curved sides. For example, the display area DA may have shapes such as a polygon, a circle, a semicircle, and an ellipse.

In embodiments, the display panel 110 may have a flat display surface. In other embodiments, the display panel 110 may have a display surface that is at least partially round. In embodiments, the display panel 110 may be bendable, foldable, or rollable. In these cases, the display panel 110 and/or the substrate SUB may include materials having flexible properties.

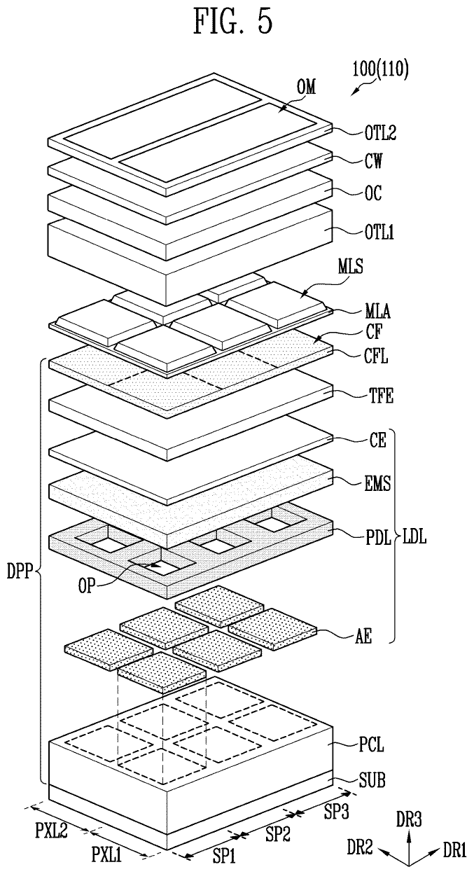

FIG. 5 is a schematic exploded perspective view illustrating a portion of a display device 100 in accordance with embodiments of the disclosure. In FIG. 5, for clear and concise description, a portion of the display panel 110 corresponding to two pixels PXL1 and PXL2 among the pixels PXL of FIG. 4 is schematically shown. A portion of the display panel 110 corresponding to remaining pixels may be similarly configured.

Referring to FIGS. 4 and 5, each of the first and second pixels PXL1 and PXL2 may include first to third sub-pixels SP1 to SP3. However, embodiments are not limited thereto. For example, each of the first and second pixels PXL1 and PXL2 may include four sub-pixels or two sub-pixels.

In FIG. 5, the first to third sub-pixels SP1 to SP3 may have quadrangle shapes when viewed in a third direction DR3 crossing the first and second directions DR1 and DR2, and have sizes equal to each other. However, embodiments are not limited thereto. According to embodiments, the first sub-pixel SP1, the second sub-pixel SP2, and the third sub-pixel SP3 may be modified to have various shapes and sizes.

The display panel 110 may include a substrate SUB, a display part DPP, a micro-lens array MLA, a first optical system OTL1, and a second optical system OTL2.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In other embodiments, the substrate SUB may include a glass substrate. In still other embodiments, the substrate SUB may include a polyimide (PI) substrate.

The display part DPP may be disposed on the substrate SUB. The display part DPP may include a pixel circuit layer PCL, a light emitting element layer LDL, an encapsulation layer TFE, and a color filter layer CFL.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may function as at least a portion of circuit elements, lines, and the like. The conductive patterns may include metal such as copper, but embodiments are not limited thereto.

The circuit elements may include the sub-pixel circuit SPC (refer to FIG. 2) for each of the first to third sub-pixels SP1 to SP3. Each transistor may include a semiconductor portion including a source area, a drain area, and a channel area, and a gate electrode overlapping the semiconductor portion, for example, the channel area. In embodiments, when the substrate SUB is provided as a silicon substrate, the semiconductor portion may be included in the substrate SUB, and the gate electrode may be included in the pixel circuit layer PCL as a conductive pattern of the pixel circuit layer PCL. In embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer interposed therebetween.

The wires of the pixel circuit layer PCL may include signal lines connected to each of the first to third sub-pixels SP1 to SP3, for example, a gate line, an emission control line, a data line, and the like. The wires may further include lines connected to the first power voltage node VDDN of FIG. 2. In addition, the wires may further include lines connected to the second power voltage node VSSN of FIG. 2.

The light emitting elements LD may include the anode electrodes AE, a pixel defining layer PDL, a light emitting structure EMS, and the cathode electrode CE.

The anode electrodes AE may be disposed on the pixel circuit layer PCL. The anode electrodes AE may contact the circuit elements of the pixel circuit layer PCL. The anode electrodes AE may include an opaque conductive material capable of reflecting light, but embodiments are not limited thereto.

The pixel defining layer PDL may be disposed on the anode electrodes AE. The pixel defining layer PDL may include an opening OP exposing a portion of each of the anode electrodes AE. The openings OP of the pixel defining layer PDL may be light emitting areas of the first to third sub-pixels SP1 to SP3.

In embodiments, the pixel defining layer PDL may include an inorganic material. In this case, the pixel defining layer PDL may include a plurality of stacked inorganic layers. For example, the pixel defining layer PDL may include silicon oxide and silicon nitride. In other embodiments, the pixel defining layer PDL may have an organic material. However, a material of the pixel defining layer PDL is not limited thereto.

The light emitting structure EMS may be disposed on the anode electrodes AE in the opening OP of the pixel defining layer PDL. The light emitting structure EMS may include a light emitting layer configured to generate light, an electron transport layer configured to transport an electron, a hole transport layer configured to transport a hole, the like.

In embodiments, the light emitting structure EMS may at least be disposed in the opening OP of the pixel defining layer PDL. The light emitting structure EMS may be entirely disposed on the pixel defining layer PDL. In other words, the light emitting structure EMS may extend across the first to third sub-pixels SP1 to SP3. In this case, at least a portion of layers in the light emitting structure EMS may be disconnected or bent at boundaries between the first to third sub-pixels SP1 to SP3. However, embodiments are not limited thereto. For example, portions of the light emitting structure EMS corresponding to the first to third sub-pixels SP1 to SP3 may be separated from each other, and each of the portions may be disposed in the opening OP of the pixel defining layer PDL.

The cathode electrode CE may be disposed on the light emitting structure EMS. The cathode electrode CE may extend across the first to third sub-pixels SP1 to SP3. As described above, the cathode electrode CE may be provided as a common electrode for the first to third sub-pixels SP1 to SP3.

The cathode electrode CE may be a thin metal layer having a thickness sufficiently thin to transmit light emitted from the light emitting structure EMS. The cathode electrode CE may be formed of a thin metal material or a transparent conductive material having a relatively thin thickness. In embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of magnesium, silver, and a mixture thereof. However, a material of the cathode electrode CE is not limited thereto.

It may be understood that any of the anode electrodes AE, a portion of the light emitting structure EMS overlapping it, and a portion of the cathode electrode CE overlapping it configure one light emitting element LD (refer to FIG. 2). In other words, each of the light emitting elements of the first to third sub-pixels SP1 to SP3 may include one anode electrode, a portion of the light emitting structure EMS overlapping it, and a portion of the cathode electrode CE overlapping it. In each of the first to third sub-pixels SP1 to SP3, holes injected from the anode electrode AE and electrons injected from the cathode electrode CE may be transported into the light emitting layer of the light emitting structure EMS to form excitons, and, when the excitons transits from an excited state to a ground state, light may be generated. A luminance of light may be determined according to the amount of a current flowing through the light emitting layer. According to a configuration of the light emitting layer, a wavelength range of the generated light may be determined.

The encapsulating layer TFE may be disposed on the cathode electrode CE. The encapsulating layer TFT may cover the light emitting element layer LDL and/or the pixel circuit layer PCL. The encapsulating layer TFT may be configured to prevent oxygen, moisture, and/or the like from permeating to the light emitting element layer LDL. In embodiments, the encapsulating layer TFE may include a structure in which one or more inorganic layers and one or more organic layers are alternately stacked. For example, the inorganic layer may include silicon nitride, silicon oxide, silicon oxynitride, or the like. For example, the organic layer may include an organic insulating material such as acrylic resin, epoxy resin, phenol resin, polyamide resin, polyimide resin, unsaturated polyester resin, polyphenylenether resin, polyphenylenesulfide resin, or benzocyclobutene (BCB). However, materials of the organic layer and the inorganic layer of the encapsulating layer TFE are not limited thereto.

In order to improve an encapsulation efficiency of the encapsulating layer TFE, the encapsulating layer TFE may further include a thin film including aluminum oxide. The thin film including the aluminum oxide may be positioned on an upper surface of the encapsulating layer TFE facing the micro-lens array MLA and/or a lower surface of the encapsulating layer TFE facing the light emitting element layer LDL.

The thin film including the aluminum oxide may be formed through atomic layer deposition (ALD) method. However, embodiments are not limited thereto. The encapsulating layer TFT may further include a thin film formed of at least one of various materials suitable for improving the encapsulation efficiency.

The color filter layer CFL may be disposed between the encapsulating layer TFT and the micro-lens array MLA. The color filter layer CFL may be configured to filter the light emitted from the light emitting structure EMS and selectively output light of a wavelength range or a color corresponding to each sub-pixel. The color filter layer CFL may include color filters CF respectively corresponding to the first to third sub-pixels SP1 to SP3, and each of the color filters CF may pass light of a wavelength range corresponding to the corresponding sub-pixel. For example, the color filter corresponding to the first sub-pixel SP1 may pass red color light, the color filter corresponding to the second sub-pixel SP2 may pass green color light, and the color filter corresponding to the third sub-pixel SP3 may pass blue color light. According to the light emitted from the light emitting structure EMS of each sub-pixel, at least a portion of the color filters CF may be omitted.

The micro-lens array MLA may be disposed on the color filter layer CFL. The micro-lens array MLA may include micro-lenses MLS respectively corresponding to the first to third sub-pixels SP1 to SP3. Each of the micro-lenses MLS may improve light emission efficiency by outputting light emitted from the light emitting structure EMS in an intended path. The micro-lens array MLA may have a relatively high refractive index. For example, the micro-lens array MLA may have a higher refractive index than an overcoat layer OC. In embodiments, the micro-lens array MLA may include an organic material. In embodiments, the micro-lenses MLS may include an acrylate material. However, the material of the micro-lenses MLS is not limited thereto.

In embodiments, compared to the opening OP of the pixel defining layer PDL, at least some of the color filter CF of the color filter layer CFL and at least some of the micro-lenses MLS of the micro-lens array MLA may be shifted in a direction parallel to a plane defined by the first and second directions DR1 and DR2. Specifically, in the center area of the display area DA, the center of the color filter CF and the center of the micro-lens MLS may be aligned or overlapped with the center of the opening OP of the corresponding pixel defining layer PDL when viewed in the third direction DR3. For example, in the center area of the display area DA, the opening OP of the pixel defining layer PDL may completely overlap the corresponding color filter CF of the color filter layer CFL and the corresponding micro-lens MLS of the micro-lens array MLA. In an area of the display area DA adjacent to the non-display area NDA, the center of the color filter CF and the center of the micro-lens MLS may be shifted in a planar direction from the center of the opening OP of the corresponding pixel defining layer PDL when viewed in the third direction DR3. For example, the area of the display area DA adjacent to the non-display area NDA, the opening OP of the pixel defining layer PDL may partially overlap the corresponding color filter CF of the color filter layer CFL and the corresponding micro-lens MLS of the micro-lens array MLA. Accordingly, in the center of the display area DA, light emitted from the light emitting structure EMS may be efficiently outputted in the normal direction of the display surface. Light emitted from the light emitting structure EMS at a peripheral area of the display area DA may be efficiently outputted in a direction inclined by a predetermined angle with respect to the normal direction of the display surface.

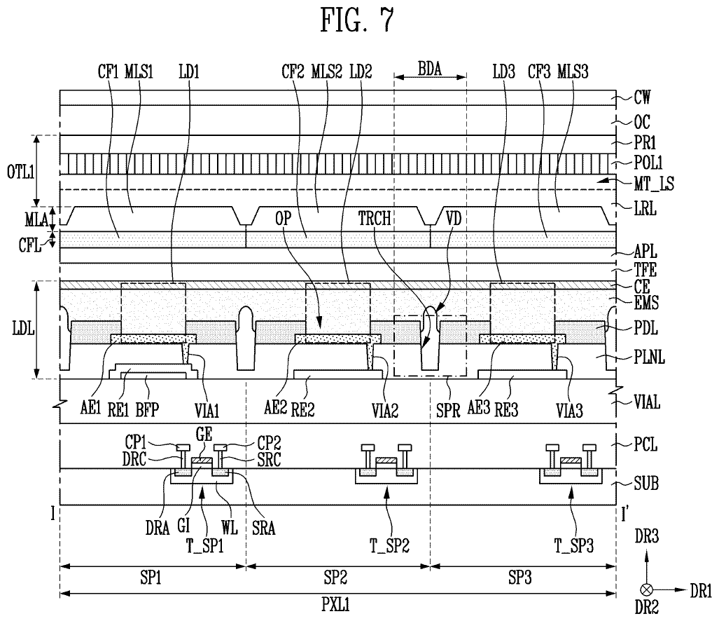

The first optical system OTL1 (or a first optical layer) may be disposed on the micro-lens array MLA. The first optical system OTL1 may include polarizing elements and may convert a polarization state of light emitted by each of the first to third sub-pixels SP1 to SP3. The first optical system OTL1 may include a lens portion (for example, a meta-lens MT_LS, refer to FIG. 7), a polarizing layer (for example, a first polarizing layer POL1, refer to FIG. 7), and a phase retardation layer (for example, a first phase retardation layer PR1, refer to FIG. 7). The lens portion may control the path of light passing through the micro-lens array MLA to correspond to a set chief ray angle CRA (or a set chief ray direction) of the second optical system OTL2. The phase retardation layer may convert the polarization state of light according to a wavelength of light passing through the lens portion.

The overcoat layer OC may be disposed on the first optical system OTL1. The overcoat layer OC may cover the first optical system OTL1, the micro-lens array MLA, the display part DPP, and the like. The overcoat layer OC may include various materials suitable for protecting lower layers thereof from foreign substances such as dust and moisture. For example, the overcoat layer OC may include at least one of an inorganic insulating layer and an organic insulating layer. For example, the overcoat layer OC may include an epoxy resin, but embodiments are not limited thereto. The overcoat layer OC may have a lower refractive index than the micro-lens array MLA.

A cover window CW may be disposed on the overcoat layer OC. The cover window CW may be configured to protect lower layers thereof. According to embodiments, the cover window CW may have a higher refractive index than the overcoat layer OC. The cover window CW may include glass, film, plastic, and the like. For example, the cover window CW may be an encapsulation film configured to protect components disposed thereunder. In other embodiments, the cover window CW may be omitted.

The second optical system OTL2 (or a second optical layer) may be disposed on the cover window CW. The second optical system OTL2 may include optical members OM overlapping the display part DPP. The second optical system OTL2 may include polarizing elements, and may convert a polarization state of light emitted by each of the first to third sub-pixels SP1 to SP3. The second optical system OTL2 may include a pancake lens. The pancake lens may be a lens that uses folded optics and means a lens structure in which a plurality of lenses and polarizing elements overlap.

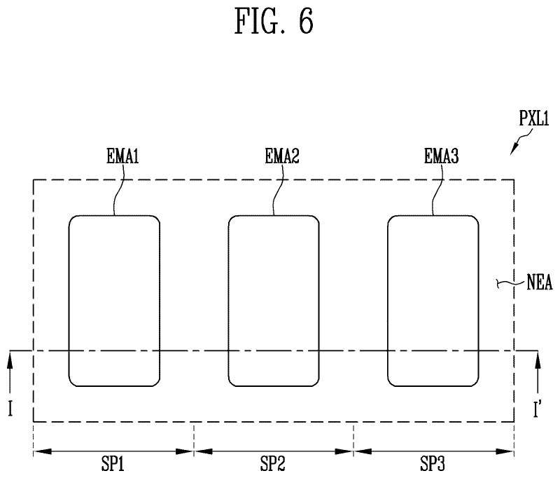

FIG. 6 is a schematic plan view illustrating an embodiment of one of the pixels of FIG. 5. In FIG. 6, the first pixel PXL1 among the first and second pixels PXL1 and PXL2 of FIG. 5 is schematically shown for clear and concise description. The remaining pixels may be configured similarly to the first pixel PXL1.

Referring to FIGS. 5 and 6, the first pixel PXL1 may include the first sub-pixel SP1, the second sub-pixel SP2, and the third sub-pixel SP3 arranged in the first direction DR1.

The first sub-pixel SP1 may include a first light emitting area EMA1 and a non-light emitting area NEA around the first light emitting area EMA. The second sub-pixel SP2 may include a second light emitting area EMA2 and a non-light emitting area NEA around the second light emitting area EMA2. The third sub-pixel SP3 may include a third light emitting area EMA3 and a non-light emitting area NEA around the third light emitting area EMA3.

The first light emitting area EMA1 may be an area where light is emitted from a light emitting layer corresponding to the first sub-pixel SP1. The second light emitting area EMA2 may be an area where light is emitted from a light emitting layer corresponding to the second sub-pixel SP2. The third light emitting area EMA3 may be an area where light is emitted from a light emitting layer corresponding to the third sub-pixel SP3. Each light emitting area may be understood as the opening OP (refer to FIG. 5) of the pixel defining layer PDL (refer to FIG. 5) corresponding to each of the first to third sub-pixels SP1 to SP3.

The first sub-pixel SP1, the second sub-pixel SP2, and the third sub-pixel SP3 may substantially have the same area, but the embodiment is not limited thereto. In some embodiments, the second sub-pixel SP2 may have an area greater than an area of the first sub-pixel SP1, and the third sub-pixel SP3 may have an area greater than the area of the second sub-pixel SP2.

The first sub-pixel SP1, the second sub-pixel SP2, and the third sub-pixel SP3 may have a polygonal shape. For example, the first sub-pixel SP1, the second sub-pixel SP2, and the third sub-pixel SP3 may have a quadrangular shape or a hexagonal shape, but the embodiment is not limited thereto. In some embodiments, the first sub-pixel SP1, the second sub-pixel SP2, and the third sub-pixel SP3 may have a circular shape, a semi-elliptical shape, and the like.

The arrangement of the sub-pixels shown in FIG. 6 is merely illustrative, and embodiments are not limited thereto. Each pixel may include two or more sub-pixels, and the sub-pixels may be arranged in various manners. Each of the sub-pixels may have various shapes, and each of emission areas of the sub-pixels may have various shapes.

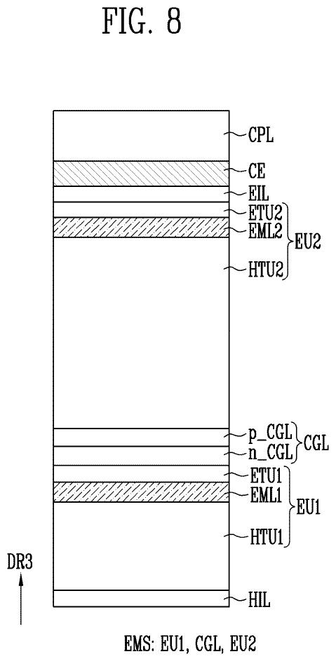

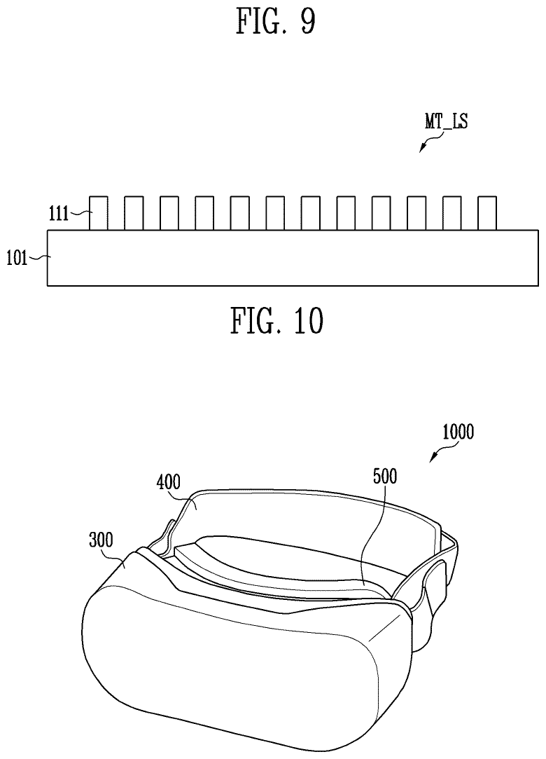

FIG. 7 is a schematic cross-sectional view taken along the line I~I′ of FIG. 6. FIG. 8 is a schematic cross-sectional view illustrating a portion of a light emitting element layer included in the display device of FIG. 7. FIG. 9 is a schematic cross-sectional view illustrating the meta-lens MT_LS of FIG. 7.

Referring to FIG. 6 to FIG. 9, the first pixel PXL1 may include the first sub-pixel SP1, the second sub-pixel SP2, and the third sub-pixel SP3.

Each of the first to third sub-pixels SP1 to SP3 may include a substrate SUB and a pixel circuit layer PCL disposed on the substrate SUB.

The substrate SUB may include a silicon wafer substrate formed using a semiconductor process. For example, the substrate SUB may include silicon, germanium, and/or silicon-germanium.

The pixel circuit layer PCL may be disposed on the substrate SUB. The substrate SUB and the pixel circuit layer PCL may include circuit elements for each of the first to third sub-pixels SP1 to SP3. For example, the substrate SUB and the pixel circuit layer PCL may include a transistor T_SP of the first sub-pixel SP1, a transistor T_SP of the second sub-pixel SP2, and a transistor T_SP of the third sub-pixel SP3. The transistor T_SP of the first sub-pixel SP1 may be one of the transistors included in the sub-pixel circuit (see “SPC” in FIG. 2) of the first sub-pixel SP1, the transistor T_SP of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 7, for clear and concise description, one of the transistors of each sub-pixel is shown and the remaining circuit elements are omitted.

The transistor T_SP1 of the first sub-pixel SP1 may include a source area SRA, a drain area DRA, and a gate electrode GE.

The source area SRA and the drain area DRA may be disposed within the substrate SUB. A well WL may be disposed in the substrate SUB through an ion injection process, and the source area SRA and the drain area DRA may be disposed to be spaced apart from each other within the well WL. The area between the source area SRA and the drain area DRA within the well WL may be defined as a channel area.

The gate electrode GE overlaps the channel area between the source area SRA and the drain area DRA, and may be disposed on the pixel circuit layer PCL. The gate electrode GE may be separated from the well WL or the channel area by an insulating material such as a gate insulating layer GI. The gate electrode GE may include a conductive material.

A plurality of layers included in the pixel circuit layer PCL may include insulating layers and conductive patterns disposed between the insulating layers. The conductive patterns may include a first conductive pattern CP1 and a second conductive pattern CP2. The first conductive pattern CP1 may be electrically connected to the drain area DRA through a drain connection portion DRC penetrating one or more insulating layers. The second conductive pattern CP2 may be electrically connected to the source area SRA through a source connection portion SRC penetrating one or more insulating layers.

As the gate electrode GE and the first and second conductive patterns CP1 and CP2 are electrically connected to other circuit elements and/or wires, the transistor T_SP1 of the fist sub-pixel SP1 may be provided as one of transistors configured the sub-pixel circuit of the first sub-pixel SP1.

Each of the transistor T_SP2 of the second sub-pixel SP2 and the transistor T_SP3 of the third sub-pixel SP3 may be configured to be substantially the same as the transistor T_SP1 of the first sub-pixel SP1.

As described above, the substrate SUB and the pixel circuit layer PCL may include circuit elements for each of the first to third sub-pixels SP1 to SP3.

A via layer VIAL may be disposed on the pixel circuit layer PCL. The via layer VIAL covers the pixel circuit layer PCL, and may have an overall flat (or uniform) surface. The via layer VIAL may include at least one of a silicon oxide, a silicon nitride, and a silicon carbon nitride, but embodiments are not limited thereto.

The light emitting element layer LDL may be disposed on the via layer VIAL. The light emitting element layer LDL may include first to third reflective electrodes RE1 to RE3, a planarization layer PLNL, first to third anode electrodes AE1 to AE3, a pixel defining layer PDL, a light emitting structure EMS, and a cathode electrode CE.

The first to third reflective electrodes RE1 to RE3 may be disposed in the first to third sub-pixels SP1 to SP3 on the via layer VIAL, respectively. For example, the first reflective electrode RE1 may be disposed on the via layer VIAL of the first sub-pixel SP1, the second reflective electrode RE2 may be disposed on the via layer VIAL of the second sub-pixel SP2, and the third reflective electrode RE3 may be disposed on the via layer VIAL of the third sub-pixel SP3. Each of the first to third reflective electrodes RE1 to RE3 may contact a circuit element disposed on the pixel circuit layer PCL through a via penetrating the via layer VIAL.

The first to third reflective electrodes RE1 to RE3 may function as full mirrors that reflect light emitted from the light emitting structure EMS toward the display surface (or the cover window CW). The first to third reflective electrodes RE1 to RE3 may include metallic materials suitable for reflecting light. For example, the first to third reflective electrodes RE1 to RE3 may include at least one of aluminum, silver, magnesium, platinum, palladium, gold, nickel, neodymium, iridium, chromium, and titanium, or may include at least one of alloys of two or more materials selected therefrom. However, the materials of the first to third reflective electrodes RE1 to RE3 are not limited to the above-described embodiment.

The first reflective electrode RE1, the second reflective electrode RE2, and the third reflective electrode RE3 may have the same thickness. For example, the thickness of each of the first reflective electrode RE1, the second reflective electrode RE2, and the third reflective electrode RE3 may be about 700 Å to about 1000 Å, or about 850 Å, but embodiments are not limited thereto.

In some embodiments, a connection electrode may be disposed below each of the first to third reflective electrodes RE1 to RE3. The connection electrode may be provided to improve the electrical connection characteristics between the corresponding reflective electrode and the circuit element of the pixel circuit layer PCL. The connection electrode may be configured of a multi-layered layer. For example, the multi-layered layer may include a structure in which titanium/titanium nitride (or titanium nitride)/tantalum nitride (or tantalum nitride) is stacked, but is not limited thereto. In some embodiments, the corresponding reflective electrode may be disposed between the layers configuring the connection electrode.

In embodiments, a buffer pattern BFP may be disposed below at least one of the first to third reflective electrodes RE1 to RE3. For example, the buffer pattern BFP may be disposed between the first reflective electrode RE1 and the via layer VIAL. The buffer pattern BFP may include an inorganic material such as a silicon carbon nitride, but is not limited thereto. By disposing the buffer pattern BFP, the height of the corresponding reflective electrode in the third direction DR3 may be adjusted. For example, the buffer pattern BFP may adjust the height of the first reflective electrode RE1, between the first reflective electrode RE1 and the via layer VIAL. The first reflective electrode RE1 may cover an upper surface and both side surfaces (or both end portions) of the buffer pattern BFP to entirely cover the buffer pattern BFP. One area of the first reflective electrode RE1 may extend to an upper surface of the via layer VIAL contacting both side surfaces of the buffer pattern BFP.

In the second sub-pixel SP2, the buffer pattern BFP described above may not disposed between the second reflective electrode RE2 and the via layer VIAL, and the second reflective electrode RE2 may be directly disposed on the via layer VIAL. In addition, in the third sub-pixel SP3, the buffer pattern BFP described above may not be disposed between the third reflective electrode RE3 and the via layer VIAL, the third reflective electrode RE3 may be directly disposed on the via layer VIAL.

The first to third reflective electrodes RE1 to RE3 may function as full mirrors, and the cathode electrode CE may function as a half mirror. Light emitted from the light emitting structure EMS may be amplified at least partially by reciprocating between the reflective electrode and the cathode electrode CE, and the amplified light may be outputted through the cathode electrode CE. As such, the distance between each reflective electrode and the cathode electrode CE may be understood as a resonance distance for the light emitted from the light emitting layer of the corresponding light emitting structure EMS.

In FIG. 7, the buffer pattern BFP is shown to be provided in the first sub-pixel SP1 and not in the second and third sub-pixels SP2 and SP3, but the embodiments are not limited thereto. In some embodiments, the buffer pattern BFP may be also provided in at least one of the second and third sub-pixels SP2 and SP3, so that the resonance distance of at least one of the second and third sub-pixels SP2 and SP3 may be adjusted.

The planarization layer PLNL may be provided to planarize steps between the first to third reflective electrodes RE1 to RE3. The planarization layer PLNL may be disposed on the via layer VIAL and the first to third reflective electrodes RE1 to RE3. The planarization layer PLNL may entirely cover the first to third reflective electrodes RE1 to RE3 and the via layer VIAL, and may have a flat surface. The planarization layer PLNL may include an insulating material such as a silicon oxide and a silicon nitride, but embodiments are not limited thereto. In some embodiments, the planarization layer PLNL may be omitted.

In embodiments, the planarization layer PLNL may include a via that exposes one area of the reflective electrode. For example, the planarization layer PLNL may include a first via VIA1 exposing one area of the first reflective electrode RE1, a second via VIA2 exposing one area of the second reflective electrode RE2, and a third via VIA3 exposing one area of the third reflective electrode RE3.

The first anode electrode AE1, the second anode electrode AE2, and the third anode electrode AE3 may be disposed on the planarization layer PLNL. For example, the first anode electrode AE1 may be disposed on the planarization layer PLNL to overlap the first reflective electrode RE1, the second anode electrode AE2 may disposed on the planarization layer PLNL to overlap the second reflective electrode RE2, and the third anode electrode AE3 may disposed on the planarization layer PLNL to overlap the third reflective electrode RE3.

The first to third anode electrodes AE1 to AE3 may have shapes similar to the first to third light emitting areas EMA1 to EMA3 of FIG. 6 when viewed in the third direction DR3. For example, the first anode electrode AE1 may have a shape similar to that of the first light emitting area EMA1 when viewed in the third direction DR3, the second anode electrode AE2 may have a shape similar to that of the second light emitting area EMA2 when viewed in the third direction DR3, and the third anode electrode AE3 may have a shape similar to that of the third light emitting area EMA3 when viewed in the third direction DR3, but embodiments are not limited thereto.

Each of the first to third anode electrodes AE1 to AE3 may be electrically connected to a corresponding reflective electrode. For example, the first anode electrode AE1 may be electrically connected to the first reflective electrode RE1 through the first via VIA1 penetrating the planarization layer PLNL. The second anode electrode AE2 may be electrically connected to the second reflective electrode RE2 through the second via VIA2 penetrating the planarization layer PLNL. The third anode electrode AE3 may be electrically connected to the third reflective electrode RE3 through the third via VIA3 penetrating the planarization layer PLNL.

In embodiments, the first anode electrode AE1 may be located within the first via VIA1 to directly contact and be connected to the first reflective electrode RE1 exposed by the first via VIA1. The second anode electrode AE2 may be located within the second via VIA2 to directly contact and be connected to the second reflective electrode RE2 exposed by the second via VIA2. The third anode electrode AE3 may be located within the third via VIA3 to directly contact and be connected to the third reflective electrode RE3 exposed by the third via VIA3.

The first to third anode electrodes AE1 to AE3 may include at least one of a transparent conductive materials such as an indium tin oxide (ITO), an indium zinc oxide (IZO), a zinc oxide (ZnOx), an indium gallium zinc oxide (IGZO), and an indium tin zinc oxide (ITZO). However, the materials of the first to third anode electrodes AE1 to AE3 are not limited thereto. For example, the first to third anode electrodes AE1 to AE3 may include a titanium nitride.

In embodiments, the first to third anode electrodes AE1 to AE3 may have the same thickness. For example, the thickness of each of the first anode electrode AE1, the second anode electrode AE2, and the third anode electrode AE3 may be about 700 Å to about 1000 Å, but is not limited thereto.

Insulating layers for adjusting a height of one or more of the first to third anode electrodes AE1 to AE3 may be further provided. The insulating layers may be disposed between one or more of the first to third anode electrodes AE1 to AE3 and the corresponding electrodes. In this case, the planarization layer PLNL and/or the buffer pattern BFP may be omitted.

The pixel defining layer PDL may be disposed on some of the first to third anode electrodes AE1 to AE3 and the planarization layer PLNL. The pixel defining layer PDL may include an opening OP exposing a portion of each of the first to third anode electrodes AE1 to AE3. The opening OP of the pixel defining layer PDL may define the light emitting area of each of the first to third sub-pixels SP1 to SP3. The pixel defining layer PDL may be disposed in the non-light emitting area (see “NEA” in FIG. 6) and may define the first light emitting area EMA1, the second light emitting area EMA2, and the third light emitting area EMA3 described with reference to FIG. 6.

In embodiments, the pixel defining layer PDL may include a plurality of inorganic insulating layers. Each of the plurality of inorganic insulating layers may include at least one of a silicon oxide and a silicon nitride. For example, the pixel defining layer PDL may include first to third inorganic insulating layers sequentially stacked, and each of the first to third inorganic insulating layers may include a silicon nitride, a silicon oxide, and a silicon oxynitride. However, the material of the pixel defining layer PDL is not limited to the above-described embodiment.

A separator SPR may be provided in the boundary area BDA between the sub-pixels adjacent to each other. The separator SPR may cause a discontinuity to be formed within the light emitting structure EMS in the boundary area BDA. For example, the light emitting structure EMS may be disconnected or bent in the boundary area BDA by the separator SPR.

The separator SPR may be provided in or on the pixel defining layer PDL. The pixel defining layer PDL may include one or more trenches TRCH as the separator SPR in the boundary area BDA. In embodiments, one or more trenches TRCH may be formed to penetrate the pixel defining layer PDL and partially penetrate the planarization layer PLNL. In other embodiments, one or more trenches TRCH may penetrate the pixel defining layer PDL and the planarization layer PLNL, and may partially penetrate the via layer VIAL. In still other embodiments, one or more trenches TRCH may at least partially penetrate the planarization layer PLNL and/or the via layer VIAL, and a portion of the pixel defining layer PDL may be disposed within one or more trenches TRCH. In still other embodiments, one or more trenches TRCH may be formed to partially penetrate the pixel defining layer PDL.

One or more trenches TRCH may be provided in the boundary area BDA. For example, one trench TRCH may be disposed in the boundary area BDA between the second sub-pixel SP2 and the third sub-pixel SP3. However, it is not limited thereto, and two or more trenches or three or more trenches separated from each other may be disposed in the boundary area BDA.

Due to the trench TRCH, discontinuous portions such as one or more voids VD in the boundary area BDA may be formed in the light emitting structure EMS. Some of the plurality of layers stacked within the light emitting structure EMS (or components included within the light emitting structure EMS) may be disconnected or bent by one or more voids VD. For example, at least one charge generation layer included in the light emitting structure EMS may be disconnected in one or more voids VD. As described above, due to one or more trenches TRCH, the light emitting structure EMS included in the first to third sub-pixels SP1 to SP3 may be at least partially separated.

One or more trenches TRCH may include or be defined by (or formed by) at least a portion of the pixel defining layer PDL penetrated and a portion of the planarization layer PLNL recessed. One or more trenches TRCH may be formed by etching method, for example, a dry etching method, but is not limited thereto. In other words, the one or more trenches TRCH are formed by removing at least a portion of the pixel defining layer PDL and the planarization layer PLNL from the upper surface of the pixel defining layer PDL toward the lower surface of the planarization layer PLNL.

In FIG. 7, it is shown that one void VD is formed in the light emitting structure EMS in the boundary are BDA, but this is an example, and embodiments are not limited thereto. For example, a valley of a concave shape may be formed in the light emitting structure EMS in the boundary BDA. Depending on the shape of the one or more trenches TRCH, the shape of the discontinuous portion formed in the light emitting structure EMS, for example, the shape of the one or more voids VD may be variously changed.

In embodiments, the light emitting structure EMS may be formed through processes such as vacuum deposition or inkjet printing. In this case, the same material as some of the components included in the light emitting structure EMS may be disposed on the bottom surfaces of the one or more trenches TRCH adjacent to the via layer VIAL.

The separator SPR may be variously deformed to allow the light emitting structure EMS to be able to have a discontinuity in the boundary area BDA. In embodiments, additional inorganic insulating patterns (or inorganic insulating layers) may be provided on the pixel defining layer PDL in the boundary area BDA without one or more trenches TRCH. A width of the uppermost inorganic insulating pattern among the additionally stacked inorganic insulating patterns may be greater than a width of the inorganic insulating pattern disposed directly below the uppermost inorganic insulating pattern. For example, in the boundary area BDA, the first to third inorganic insulating patterns are sequentially stacked from the pixel defining layer PDL, and the uppermost third inorganic insulating pattern may have a larger width than the second inorganic insulating pattern. In this case, the pixel defining layer PDL may have a cross-section of a “T” or “I” shape in the boundary area BDA. Depending on the shape of the pixel defining layer PDL, a plurality of layers included in the light emitting structure EMS may be at least partially disconnected or bent in the boundary area BDA.

The light emitting structure EMS may be disposed on the anode electrode (see “AE” in FIG. 5) exposed by the opening OP of the pixel defining layer PDL. The light emitting structure EMS may fill the opening OP of the pixel defining layer PDL, and may be disposed entirely across the first to third sub-pixels SP1 to SP3. As described above, the light emitting structure EMS may be at least partially disconnected or bent in the boundary area BDA by the separator SPR. Accordingly, when the display panel (see “110” in FIG. 5) operates, the current leaking from each of the first to third sub-pixels SP1 to SP3 to the neighboring sub-pixel through the layers included in the light emitting structure EMS may decrease. Accordingly, the first light emitting element LD1, the second light emitting element LD2, and the third light emitting element LD3 may operate with relatively high reliability.

The cathode electrode CE may be disposed on the light emitting structure EMS. The cathode electrode CE may be provided commonly for the first to third sub-pixels SP1 to SP3. The cathode electrode CE may function as a half mirror that partially transmits and partially reflects light emitted from the light emitting structure EMS.

The first anode electrode AE1, the portion of the light emitting structure EMS overlapping the first anode electrode AE1, and the portion of the cathode electrode CE overlapping the first anode electrode AE1 may configure the first light emitting element LD1. The second anode electrode AE2, the portion of the light emitting structure EMS overlapping the second anode electrode AE2, and the portion of the cathode electrode CE overlapping the second anode electrode AE2 may configure the second light emitting element LD2. The third anode electrode AE3, the portion of the light emitting structure EMS overlapping the third anode electrode AE3, and the portion of the cathode electrode CE overlapping the third anode electrode AE3 may configure the third light emitting element LD3. The light emitting structure EMS in each of the first to third light emitting elements LD1 to LD3 may be configured substantially the same, but is not limited thereto. In embodiments, the light emitting structure EMS may be formed in a vacuum deposition method.

The light emitting structure EMS may include a first light emitting unit EU1 and a second light emitting unit EU2 as shown in FIG. 8.

Each of the first and second light emitting units EU1 and EU2 may include light emitting layers for generating light according to an applied current. The first light emitting unit EU1 may include a first light emitting layer EML1, a first hole transporter HTU1, and a first electron transporter ETU1. The first light emitting layer EML1 may be disposed between the first hole transporter HTU1 and the first electron transporter ETU1. The second light emitting unit EU1 may include a second light emitting layer EML2, a second hole transporter HTU2, and a second electron transporter ETU2. The second light emitting layer EML2 may be disposed between the second hole transporter HTU2 and the second electron transporter ETU2.

According to embodiments, the light emitting structure EMS may further include a hole injection layer HIL and an electron injection layer EIL. The hole injection layer HIL may be disposed between each of the first to third anode electrodes AE1 to AE3 and the first light emitting unit EU1, and the electron injection layer EIL may be disposed between the cathode electrode CE and the second light emitting unit EU2. The hole injection layer HIL may lower an injection barrier between each of the first to third anode electrodes AE1 to AE3 and the first hole injection layer HTU1 of the first light emitting unit EU1. The hole injection layer HIL may include, but not limited to, a hole injection material and a p-type dopant. The electron injection layer EIL may lower an injection barrier between the cathode electrode CE and the second electron transporter ETU2 of the second light emitting unit EU2. The electron injection layer EIL may include, but not limited to, an electron injection material and an n-type dopant.

In embodiments, the first light emitting layer EML1 and the second light emitting layer EML2 may generate light of different colors. The light emitted from each of the first light emitting layer EML1 and the second light emitting layer EML2 may be mixed and recognized as white light. For example, the first light emitting layer EML1 may generate blue-colored light, and the second light emitting layer EML2 may generate yellow-colored light. In embodiments, the second light emitting layer EML2 may include a structure in which a first sub light emitting layer configured to generate red-colored light and a second sub light emitting layer configured to generate green-colored light are stacked. The red-colored light and the green-colored light may be mixed to provide yellow light. In this case, a layer for transporting holes and/or a function for blocking transport of electrons may be further disposed between the first and second sub light emitting layers.

The light emitting structure EMS may further include an intermediate layer CGL. The intermediate layer CGL (or a charge generation layer) may be disposed between the first light emitting unit EU1 and the second light emitting unit EU2. The intermediate layer CGL may interconnect the first light emitting unit EU1 and the second light emitting unit EU2. The intermediate layer CGL may be conductive by including a material of relatively higher charge conductivity (or charge mobility) than the first and second light emitting units EU1 and EU2.

The intermediate layer CGL may include an n-type charge generation layer n_CGL and a p-type charge generation layer p_CGL sequentially stacked. In at least the light emitting area EMA, the n-type charge generation layer n_CGL may provide electrons to the first electron transporter ETU1 of the first light emitting unit EU1, and the p-type charge generation layer p_CGL may provide holes to the second hole transporter HTU2 of the second light emitting unit EU2.

The first light emitting unit EU1 and the second light emitting unit EU2 may include a material of relatively lower charge conductivity (or charge mobility) than the intermediate layer CGL. In embodiments, the first light emitting unit EU1 and the second light emitting unit EU2 may include a material with relatively greater insulation properties than the intermediate layer CGL. In this case, even if the first and second light emitting units EU1 and EU2 are interconnected on the trench TRCH, no current may be transmitted to adjacent sub-pixels.

The first light emitting unit EU1 may be disposed on the pixel defining layer PDL and the first to third anode electrodes AE1 to AE3. The intermediate layer CGL may be disposed on the first light emitting unit EU1. The second light emitting unit EU2 may be disposed on the intermediate layer CGL. The cathode electrode CE may be disposed on the second light emitting unit EU2. A capping layer CPL including an inorganic material may be disposed on the cathode electrode CE to protect the cathode electrode CE.

The first to third light emitting elements LD1 to LD3 including the above-described configurations may have a strong resonance structure. In this case, the spectrum of light emitted from each of the first to third light emitting elements LD1 to LD3 is narrowed, so that only light in a narrow wavelength range is strongly emitted, and light having a wavelength other than the corresponding wavelength may be reduced. Accordingly, the amount of light emitted from the front direction in each of the first to third sub-pixels SP1 to SP3 may increase, and the amount of light emitted from the side direction in each of the first to third sub-pixels SP1 to SP3 may decrease. Therefore, the front light emitting luminance of each of the first to third sub-pixels SP1 to SP3 may increase and the side light emitting luminance of each of the first to third sub-pixels SP1 to SP3 may decrease. The strong resonance structure may be implemented by controlling a gap between components included in the first to third light emitting elements LD1 to LD3. For example, when a thickness of the cathode electrode CE of each of the first to third light emitting elements LD1 to LD3 is designed to be relatively thick, the first to third light emitting elements LD1 to LD3 may have a strong resonance structure.

The encapsulation layer TFE may be disposed on the cathode electrode CE. The encapsulation layer TFE may prevent oxygen and/or moisture from penetrating into the light emitting element layer LDL.

The color filter layer CFL may be disposed on the encapsulation layer TFE. In embodiments, the color filter layer CFL may be attached to the encapsulation layer TFE using an adhesive layer APL. For example, the color filter layer CFL may be manufactured separately and attached to the encapsulation layer TFE using the adhesive layer APL. The adhesive layer APL may further perform a function of protecting the lower layers including the encapsulation layer TFE.

The color filter layer CFL may include first to third color filters CF1 to CF3 corresponding to the first to third sub-pixels SP1 to SP3 respectively. For example, the color filter layer CFL may include the first color filter CF1 corresponding to the first sub-pixel SP1, the second color filter CF2 corresponding to the second sub-pixel SP2, and the third color filter CF3 corresponding to the third sub-pixel SP3. The first to third color filters CF1 to CF3 may pass light of different wavelength ranges. For example, the first color filter CF1 may pass light of the red color, the second color filter CF2 may pass light of the green color, and the third color filter CF3 may pass light of the blue color. In this case, the first sub-pixel SP1 may be a red sub-pixel, the second sub-pixel SP2 may be a green sub-pixel, and the third sub-pixel SP3 may be a blue sub-pixel.

In embodiments, the first to third color filters CF1 to CF3 may partially overlap in the boundary area BDA. In other embodiments, the first to third color filters CF1 to CF3 may be spaced from each other, and a black matrix may be provided between the spaced first to third color filters CF1 to CF3.

The micro-lens array MLA may be disposed on the color filter layer CFL. The micro-lens array MLA may include first to third micro-lenses MLS1 to MLS3 corresponding to the first to third sub-pixels SP1 to SP3 respectively. For example, the micro-lens array MLA may include the first micro-lens MLS1 corresponding to the first sub-pixel SP1, the second micro-lens MLS2 corresponding to the second sub-pixel SP2, and the third micro-lens MLS3 corresponding to the third sub-pixel SP3. The first to third micro-lenses MLS1 to MLS3 each may output the light emitted from the first to third light emitting elements LD1 to LD3 in an intended path. Accordingly, the light emission efficiency of the first to third sub-pixels SP1 to SP3 may be improved.

The first optical system OTL1 may be directly disposed on the micro-lens array MLA.

The first optical system OTL1 may include a low refractive layer LRL disposed on the microlens array MLA, the meta-lens MT_LS,, the first polarizing layer POL1 disposed on the low refractive layer LRL and the meta-lens MT_LS, and the first phase retardation layer PR1 disposed on the first polarizing layer POL1.

The meta-lens MT_LS may include a base layer 101 and a nanostructure 111 that is hydrogenated amorphous silicon formed on the base layer 101, as shown in FIG. 9. The base layer 101 may be, but is not limited to, a fused silica glass substrate. The nanostructure 111 may have different structural variables (height, width, length, rotation angle) on a plane of the base layer 101. The structural variables of the nanostructure 111 may be determined by various factors such as a phase effect according to the polarization state of incident light, a target incident wavelength, a size and focus of a meta-lens, and the like. The nanostructure 111 may include a plurality of nanostructures having different structural variables that have a phase retardation effect and satisfy an excellent transmittance.

The meta-lens MT_LS may be disposed on the low refractive layer LRL. The low refractive layer LRL and the meta-lens MT_LS may change the light emitted from the micro-lens array MLA to correspond to the chief ray angle CRA of the second optical system (see “OTL2” in FIG. 5) by using the refractive index difference. Accordingly, the light emission luminance of the display panel (see “110” in FIG. 5) may be improved. The low refractive layer LRL includes a resin and hollow particles dispersed inside the resin and may have a refractive index in the range of 1.1 to 1.3, but is not limited thereto.

The first polarizing layer POL1 may be disposed on the meta-lens MT_LS and the low refractive layer LRL. The first polarizing layer POL1 may be a linear polarizing plate. For example, the first polarizing layer POL1 may be, but is not limited thereto, a wire grid polarizing plate having a structure in which metal wires are arranged in one direction. The first polarizing layer POL1 may be a film type or a liquid crystal coating type.

The first phase retardation layer PR1 may be disposed on the first polarizing layer POL1. The first phase retardation layer PR1 may convert a polarization state of light. For example, the first phase retardation layer PR1 may be a quarter wave plate which delays a phase of transmitted light by λ/4. For example, the first phase retardation layer PR1 may include liquid crystal molecules. The liquid crystal molecules may be oriented in a preset direction. The first phase retardation layer PR1 is a component which changes linearly polarized light to circularly polarized light and changes circularly polarized light to linearly polarized light. The first phase retardation layer PR1 may convert the linearly polarized light into left-handed circularly polarized light that rotates to the left with respect to an advancing direction or right-handed circularly polarized light that rotates to the right according to properties of the incident linearly polarized light.

The overcoat layer OC may be disposed on the first optical system OTL1, and the cover window CW may be disposed on the overcoat layer OC. According to embodiments, the overcoat layer OC and the cover window CW may be omitted.

The above-described display panel 110 may be applied to a head mounted display device mounted on a user's head to provide a screen on which an image is displayed to the user.

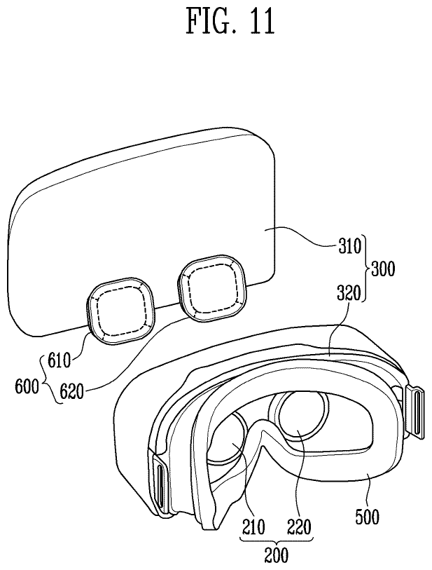

FIG. 10 is a schematic perspective view illustrating a display device 1000 according to an embodiment. FIG. 11 is a schematic exploded perspective view illustrating the display device 1000 of FIG. 10.

Referring to FIGS. 10 and 11, the display device 1000 may include a head mounted display device.

The display device 1000 may include a see-through type that provides augmented reality based on actual external objects, and a see-closed type that provides virtual reality to the user with a screen independent from an external object. Hereinafter, a see-closed type head mounted display device will be described as an example, but the present disclosure is not limited thereto.

The display device 1000 may include a display panel 600, an optical lens portion 200, a case portion 300, a fixing portion 400, and a cushion portion 500.

In embodiments, the display panel 600 may display or provide an image. The display panel 600 may emit light to display or provide a picture or an image. The display panel 600 may be the display panel 110 described with reference to FIG. 5.

The display panel 600 may be accommodated in the case portion 300. The display panel 600 may be configured to be opaque, transparent or translucent according to a type of the display device 1000. The display panel 600 may include a first display panel 610 and a second display panel 620. The first display panel 610 may be disposed to correspond to a left eye of the user, and the second display panel 620 may be disposed to correspond to a right eye of the user.

In embodiments, the display panel 600 may include a first surface (or a front surface) on which an image is displayed and a second surface (or a rear surface) opposite to the first surface.

In embodiments, the optical lens portion 200 may allow light emitted from the display panel 600 to pass therethrough. The optical lens portion 200 may refract and/or reflect light emitted from the display panel 600. The optical lens portion 200 may be disposed to face the display panel 600. When the user wears the display device 1000, the optical lens portion 200 may be disposed between the user and the display panel 600. Therefore, the user may recognize light which is emitted from the display panel 600 and is refracted and/or reflected by the optical lens portion 200.

In embodiments, the optical lens portion 200 may include a first optical lens portion 210 and a second optical lens portion 220. The first optical lens portion 210 may be disposed to correspond to the left eye of the user and be overlapped with the first display panel 610. The second optical lens portion 220 may be disposed on correspond to the right eye of the user and be overlapped with the second display panel 620.

In embodiments, the case portion 300 may accommodate the display panel 600 and the optical lens portion 200 therein. The case portion 300 may be provided with a space therein, and the display panel 600 and the optical lens portion 200 may be disposed in the space. The case portion 300 may protect the display panel 600 and the optical lens portion 200 from external impact.

In embodiments, the case portion 300 may include a cover portion 310 and a body portion 320. The case portion 300 may be separated into the cover portion 310 and the body portion 320. However, the disclosure is not limited thereto and the cover portion 310 and the body portion 320 may be integrally formed. In embodiments, the cover portion 310 may be disposed on the rear surface of the display panel 600 and the body portion 330 may be disposed on the front surface of the display panel 600.

The fixing portion 400 may fix or mount the case portion 300 on the head of the user. A length of the fixing portion 400 may be adjusted according to a circumference of the head of the user. The fixing portion 400 may include a structure such as a strap or a band which is connected to the case portion 300. The fixing portion 400 may be detachable from the case portion 300.

In embodiments, the cushion portion 500 may improve a wearing comfort to the user. When the user wears the display device 1000, the cushion portion 500 may be disposed between the user and the case portion 300. For example, the cushion portion 500 may be attached to the case portion 300. In other embodiments, the cushion portion 500 may be detachable from the case portion 300 and be omitted from the display device.

In embodiments, the display device 1000 may further include a control portion. The control portion may perform an operation for calculation of a position of a pupil of the user, calculation of a direction of a gaze of the user, image processing (or image mapping) based on the calculated position of the pupil of the user (or the calculated direction of the gaze of the user), display of a processed image on the display panel 600, and the like. The control portion may be implemented as a dedicated processor including an embedded processor or the like and/or a general-purpose processor including a central processing unit, an application processor, or the like. However, the disclosure is not limited thereto.

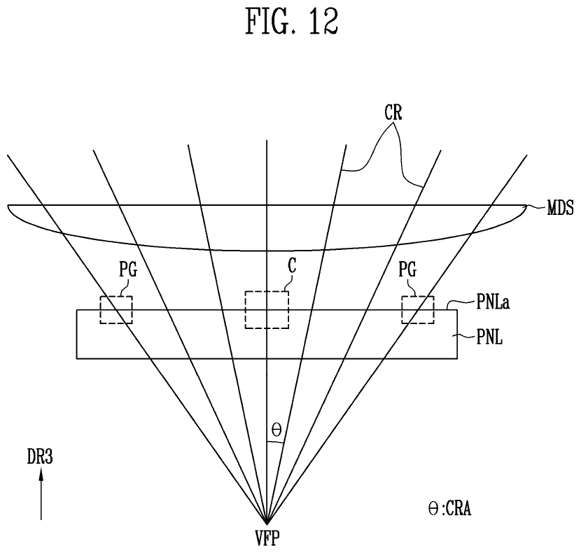

FIG. 12 is a schematic conceptual diagram for describing a chief ray CR angle incident from a display panel PNL to a module lens MDS.

Referring to FIG. 12, the display panel PNL may be applied to a head mounted display device together with the module lens MDS. The module lens MDS may include a pancake lens.

Light passing through the display panel PNL and directed to the module lens MDS may have different incident angles depending on the position of the display panel PNL. An angle of incidence of light incident on the module lens MDS may typically be defined as a chief ray angle (CRA). The chief ray CR may be a ray that starts from the virtual focus point VFP, passes through the display panel PNL, and enters the module lens MDS. The chief ray angle may be an angle formed by the chief ray CR with the normal line of the display surface PNLa of the display panel PNL.

A chief ray angle of light incident on the edge of the module lens MDS through a peripheral portion PG of the display panel PNL may be different from a chief ray angle of light incident on a center of the module lens MDS through a center C of the display panel PNL. The display panel PNL according to the embodiment sets the characteristics of the first optical system (see “OTL1” in FIG. 7) embedded therein in consideration of the above-described chief ray angle and direction of the module lens MDS. For example, the first optical system OTL1 may control the traveling path of light emitted from the light emitting element layer (see “LDL” in FIG. 7) to correspond to the chief ray angle required by the module lens MDS, and control the light incident on the module lens MDS to have a preset phase delay value regardless of a region.

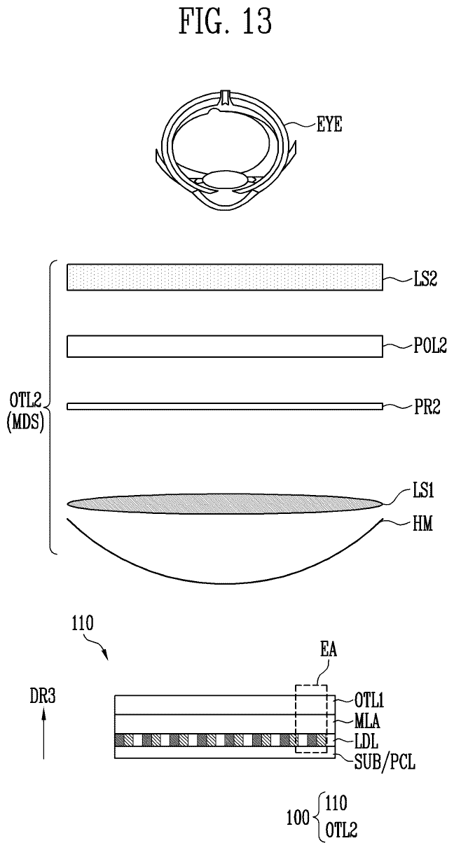

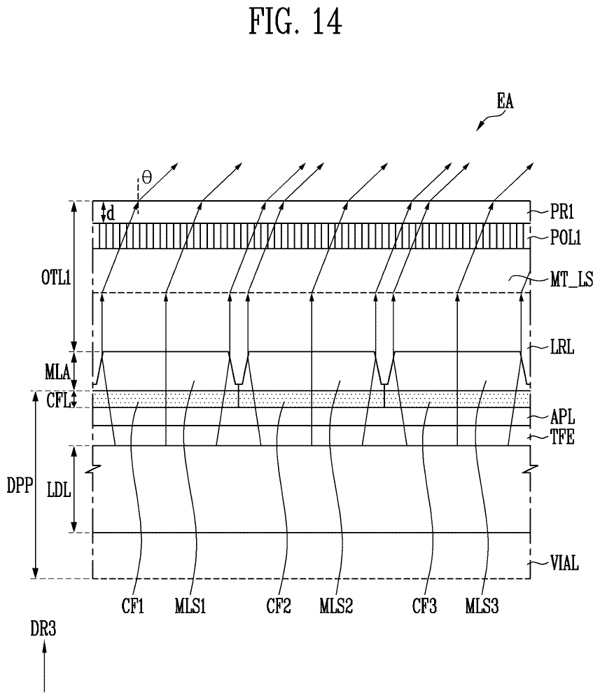

FIG. 13 is a schematic diagram illustrating a display panel 110 and a second optical system OTL2 according to an embodiment. FIG. 14 is a schematic enlarged view of portion EA shown in FIG. 13.

With respect to the embodiments of FIGS. 13 and 14, to avoid redundant descriptions, differences from the above-described embodiment will be mainly described.

Referring to FIG. 13 and FIG. 14, the second optical system OTL2 may be positioned between the display panel 110 and the user's pupil EYE. The second optical system OTL2 may be the module lens MDS described with reference to FIG. 12.

The display panel 110 may include a substrate SUB, a pixel circuit layer PCL, a light emitting element layer LDL, a micro-lens array MLA, and a first optical system OTL1.

The light emitting element layer LDL may include light emitting elements having a strong resonance structure. The resonance structure is necessarily accompanied by spectral narrowing. The strong resonance structure have very strong spectral narrowing, so that only light in a specific wavelength (or very narrow wavelength) region may be emitted strongly. Accordingly, the profile of light emitted from the light emitting element with the strong resonance structure may be narrowed.

The micro-lens array MLA may extract light emitted from a display part DPP into an intended path using micro-lenses MLS. For example, the micro-lens array MLA may focus light passing through the light emitting element layer LDL and a color filter CFL in the front direction of the display panel 110.

The first optical system OTL1 may include a low refractive layer LRL, a meta-lens MT_LS, a first polarizing layer POL1, and a first phase retardation layer PR1.

The low refractive layer LRL and the meta-lens MT_LS may be embedded in the display panel 110. The low refractive layer LRL and the meta-lens MT_LS may be disposed on the micro-lens array MLA. The low refractive layer LRL and the meta-lens MT_LS may change the path of light emitted from the light emitting element layer LDL and passing through the micro-lens array MLA by using the difference in refractive index to correspond to the chief ray angle of the second optical system (OTL2) (or the module lens (MDS)). For example, light emitted from the light emitting element layer LDL located at the edge of the display area DA may pass through the micro-lens array MLA and proceed in the third direction DR3 (or a vertical direction). Light passing through the micro-lens array MLA may proceed in a diagonal direction that is inclined in the third direction DR3 to correspond to the chief ray angle (or the chief ray direction) of the second optical system OTL2 by the low refractive layer LRL and the meta-lens MT_LS. The light proceeded in the diagonal direction may be incident on the first polarizing layer POL1.

The low refractive layer LRL and the meta-lens MT_LS may reduce the loss of light that has passed through the first optical system OTL1 by changing the path of light passing through the micro-lens array MLA to be within a specific angular range (for example, the chief ray angular range of the second optical system OTL2).

The first polarizing layer POL1 may be disposed on the meta-lens MT_LS and the low refractive layer LRL. The first polarizing layer POL1 may polarize un-polarized light in a predetermined direction. The first polarizing layer POL1 may be a polarizing member having absorptive or reflective properties.

An absorptive polarizing member may absorb light vibrating in a specific direction while transmitting polarized light (linearly polarized light) vibrating in a direction perpendicular to the specific direction. The absorptive polarizing member may have a transmission axis and an absorption axis orthogonal to the transmission axis. A reflective polarizing member may reflect light vibrating in a specific direction while transmitting polarized light (linearly polarized light) vibrating in a direction perpendicular to the specific direction. The reflective polarizing member may have a transmission axis and a reflection axis orthogonal to the transmission axis. For example, the first polarizing layer POL1 may be a wire grid polarizing plate.

Light polarized in a specific direction by the first polarizing layer POL1 may be incident on the first phase retardation layer PR1. The first phase retardation layer PR1 may be a quarter wave plate which delay the wavelength of incident light by λ/4. For example, the first phase retardation layer PR1 may convert linearly polarized light into circularly polarized light, and convert circularly polarized lights into linearly polarized light. In other embodiments, the first phase retardation layer PR1 may be a meta-surface that delays the phase of incident light by λ/4.

In embodiments, the first phase retardation layer PR1 may have different thicknesses depending on the position to correspond to the chief ray angle CRA (or the chief ray direction) of the second optical system OTL2. For example, the thickness of the first phase retardation layer PR1 may be calculated through the following formula.

$$d = 1 / 4 λ \times cos θ / n \qquad [ Formula ]$$

where, λ: a wavelength, n: a refractive index of the first phase retardation layer PR1, θ: the chief ray angle of the second optical system OTL2, d: a thickness of the first phase retardation layer PR1.

According to the above formula, the thickness of the first phase retardation layer PR1 may be determined according to the chief ray angle θ of the second optical system OTL2. For example, the chief ray angle θ of the second optical system OTL2 may increase from the center to the periphery of the display panel 110. In this case, the thickness d of the first phase retardation layer PR1 may gradually decrease from the center to the periphery of the display panel 110.

The first phase retardation layer PR1 having the thickness d that varies depending on its position to correspond to the chief ray angle θ of the second optical system OTL2 may also delay the wavelength of off-axis light incident on the first phase retardation layer PR1 by λ/4. Accordingly, the off-axis light incident on the first phase retardation layer PR1 may not be converted into elliptically polarized light while passing through the first phase retardation layer PR1, and thus may be converted into complete linearly polarized light.

The first optical system OTL1 including the above-described configurations may control the path of light passing through the micro-lens array MLA to correspond to the chief ray angle of the second optical system OTL2. In addition, the first optical system OTL1 may delay the wavelength of the off-axis light incident on the first phase retardation layer PR1 by λ/4 and emit it to the second optical system OTL2. Accordingly, the loss of light emitted from the light emitting element layer LDL and passing through the first optical system OTL1 may be reduced. Accordingly, luminance and light emission efficiency of the display panel 110 may be improved, and reliability may be improved.

The overcoat layer OC and the cover window CW described with reference to FIG. 7 may be disposed on the first optical system OTL1.

The second optical system OTL2 may include a half mirror HM, a first lens LS1, a second phase retardation layer PR2, a second polarizing layer, and a second lens LS2.

The half mirror HM may be disposed on the first optical system OTL1. The half mirror HM may partially reflect incident light. The half mirror HM may transmit light incident in the third direction DR3 (for example, light incident from a lower portion of the half mirror HM) and reflect light incident in a direction opposite to the third direction DR3 (for example, light incident at an upper portion of the half mirror HM). Only about a half of light incident onto the half mirror HM may pass through the half mirror HM. The half mirror HM may include a semi-transmissive material. The half mirror HM may include metals such as magnesium, silver, and aluminum, but the disclosure is not necessarily limited thereto. In embodiments, the half mirror HM may have a curvature, but the disclosure is not necessarily limited thereto.

The first lens LS1 may be disposed on the half mirror HM. The first lens LS1 may be disposed directly on the half mirror HM. The first lens LS1 may be disposed between the half mirror HM and the second phase retardation layer PR2. For example, the first lens LS1 may have a structure in which a convex lens and a concave lens are combined. Accordingly, the first lens LS1 may enlarge the image. In other embodiments, the first lens LS1 may focus the incident light on a focal point of a predetermined distance.

In embodiments, the half mirror HM and the first lens LS1 may be spaced apart to ensure a required optical path length. In other embodiments, the first lens LS1 may include a geometric phase lens.

The second phase retardation layer PR2 may be disposed on the first lens LS1. The second phase retardation layer PR2 may convert the polarization state of the light passing through the first lens LS1. For example, the second phase retardation layer PR2 may be a λ/4 phase retardation plate. In embodiments, the second phase retardation layer PR2 may adjust the optical path length of light passing through the second phase retardation layer PR2 in order to phase delay the wavelength of incident light by λ/4. For example, the second phase retardation layer PR2 may have the same structure as the first phase retardation layer PR1.

The second polarizing layer POL2 may be disposed on the second phase retardation layer PR2. The second polarizing layer POL2 may include a reflective polarizing plate. The second polarizing layer POL2 may transmit linearly polarized light coincident with the transmission axis and reflect linearly polarized light that is perpendicular to the transmission axis. The second polarizing layer POL2 may include, for example, a wire grid polarizing plate or a dielectric multilayer film.

The second lens LS2 may be disposed on the second polarizing layer POL2. The second lens LS2 may include a convex lens.

Light converted into circularly polarized light passing through the first optical system OTL1 may be converted into linearly polarized light while passing through the half mirror HM, the first lens LS1, and the second phase retardation layer PR2. The light converted into linearly polarized light may be reflected by the second polarizing layer POL2, may be incident on the second phase retardation layer PR2, may pass through the second phase retardation layer PR2, and may be converted into circularly polarized light again. The light converted into circularly polarized light again may be reflected by the half mirror HM, may be incident on the second phase retardation layer PR2, may pass through the second phase retardation layer PR2, and may be converted into linearly polarized light again. The light converted into linearly polarized light may transmit the second polarizing layer POL2, and may emitted to an outside of a display device 100.

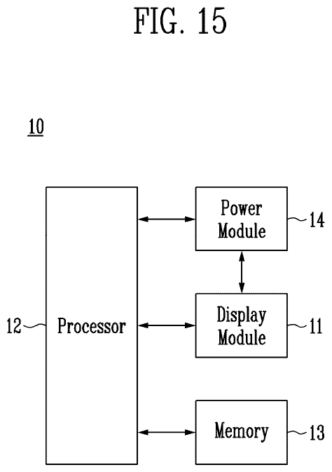

FIG. 15 is a schematic block diagram illustrating an electronic device 10 in accordance with embodiments of the disclosure.

Referring to FIG. 15, the electronic device 10 in accordance with embodiments of the disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and conversion module. The power conversion module convers power supplied by the power supply module and generates power to operate the electronic device 10.

At least one of the above-described components of the electronic device 10 may be included in the display device 100 according to embodiments as described above. In addition, in terms of functionality, some of the individual modules included in one module may be included in the display device 100 and others may be provided separately from the display device. For example, the display module 11 is included in the display device 100, whereas the processor 12, the memory 13, and the power module 14 are not included in the display device 100 and are instead provided separately in the electronic device 10.

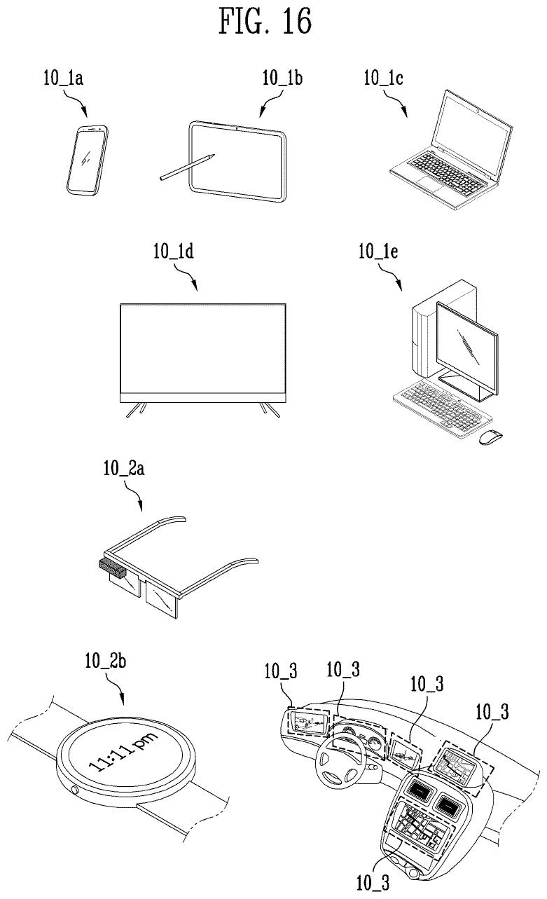

FIG. 16 shows schematic views of various embodiments of an electronic device.

Referring to FIG. 16, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as the head mounted display device 1000 described with reference to FIG. 10 and FIG. 11, smart glasses 10_2a, and a smart watch 10_2b, and an automotive electronic device 10_3 including a display module such as a center information display (CID) disposed at the instrument cluster, the center fascia, and the dashboard of a vehicle, and a room mirror display.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated.

Accordingly, it will be understood by those of skill in the art that various changes in form and details may be made without departing from the spirit and scope of the disclosure as set forth in the following claims.

What is claimed is:

1. A display device comprising:
a substrate;
a light emitting element layer disposed on the substrate and including sub-pixels emitting light;
a micro-lens array disposed on the light emitting element layer and including at least one micro-lens;
a first optical system disposed directly on the micro-lens array; and
a second optical system including a module lens and disposed above the first optical system,
wherein the first optical system includes:
a low refractive layer disposed on the micro-lens array;
a meta-lens disposed on the low refractive layer;
a first polarizing layer disposed on the meta-lens; and
a first phase retardation layer disposed on the first polarizing layer, and
wherein the first phase retardation layer has a thickness corresponding to a chief ray angle of the module lens.

2. The display device of claim 1, wherein the module lens includes a pancake lens.

3. The display device of claim 2, wherein the first phase retardation layer is a quarter wave plate.

4. The display device of claim 2, wherein the meta-lens controls a path of light passing through the micro-lens array to correspond to the chief ray angle of the pancake lens.

5. The display device of claim 4, wherein the meta-lens includes a nanostructure disposed on a base layer.

6. The display device of claim 2, wherein the light emitting element layer includes a light emitting element having a strong resonance structure.

7. The display device of claim 6, wherein the light emitting element layer includes a planarization layer disposed on the substrate and the light emitting element disposed on the planarization layer, and
wherein the light emitting element includes:
an anode electrode disposed on the planarization layer of each of the sub-pixels;
a pixel defining layer disposed on the planarization layer, the pixel defining layer defining a light emitting area of each of the sub-pixels;
a light emitting structure disposed on the pixel defining layer; and
a cathode electrode disposed on the light emitting structure.

8. The display device of claim 7, wherein the light emitting structure includes:
a first emission component disposed on the anode electrode, the first emission component emitting light;
an intermediate layer disposed on the first emission component; and
a second emission component disposed on the intermediate layer, the second emission component emitting light.

9. The display device of claim 2, wherein the first polarizing layer is a wire grid polarizing plate.

10. The display device of claim 2, wherein the second optical system includes:
a half mirror disposed above the first optical system;
a second phase retardation layer disposed on the half mirror;
a second polarizing layer disposed on the second phase retardation layer; and
at least one lens disposed on the half mirror.

11. The display device of claim 10, wherein the second phase retardation layer includes a λ/4 phase retardation plate.

12. The display device of claim 10, wherein the second polarizing layer is a reflective polarizing plate.

13. The display device of claim 10, wherein the lens includes:
a first lens disposed between the half mirror and the second phase retardation layer; and
a second lens disposed on the second polarizing layer.

14. The display device of claim 2, further comprising:
a color filter layer disposed between the light emitting element layer and the micro-lens array, the color filter layer including at least one color filter.

15. An electronic device comprising:
a display device configured to display an image; and
a processor configured to provide input image data to the display device,
wherein the display device includes:
a substrate;
a light emitting element layer disposed on the substrate and including sub-pixels emitting light;
a micro-lens array disposed on the light emitting element layer and including at least one micro-lens;
a first optical system disposed directly on the micro-lens array; and
a second optical system disposed above the first optical system and including a module lens,
wherein the first optical system includes:
a low refractive layer disposed on the micro-lens array;
a meta-lens disposed on the low refractive layer;
a first polarizing layer disposed on the meta-lens; and
a first phase retardation layer disposed on the first polarizing layer, and
wherein the first phase retardation layer has a thickness corresponding to a chief ray angle of the module lens.

16. The electronic device of claim 15, wherein the module lens includes a pancake lens.

17. The electronic device of claim 16, wherein the first phase retardation layer is a quarter wave plate.

18. The electronic device of claim 16, wherein the meta-lens controls a path of light passing through the micro-lens array to correspond to the chief ray angle of the pancake lens.

19. The electronic device of claim 18, wherein the meta-lens includes a nanostructure disposed on a base layer.

20. The electronic device of claim 15, wherein the light emitting element layer includes a light emitting element having a strong resonance structure.
